(19) United States
(12) Patent Application Publication
(10) Pub. No.: US 2011/0193590 A1
(43) Pub. Date: Aug. 11, 2011

(54) SEMICONDUCTOR DEVICE AND CIRCUIT BOARD HAVING THE SEMICONDUCTOR DEVICE MOUNTED THEREON

(75) Inventors: Hiroshi Nakagawa, Tokyo (JP); Satoru Nishimura, Tokyo (JP)

(73) Assignee: Elpida Memory, Inc., Tokyo (JP)

(21) Appl. No.: 13/019,648

(22) Filed: Feb. 2, 2011

(30) Foreign Application Priority Data
Feb. 5, 2010 (JP) 2010-024783
Jun. 28, 2010 (JP) 2010-145948

(51) Int. Cl. H03K 17/16

(52) U.S. Cl. 326/30

(57) ABSTRACT

To provide a semiconductor device including a first replica buffer connected to a calibration terminal, an impedance adjusting circuit that changes an impedance of the first replica buffer according to a comparison result between a potential of the terminal and a reference potential, and an impedance adjusting circuit that changes an impedance of a third replica buffer according to a comparison result between a potential of a connection node of a second replica buffer and the third replica buffer and a potential of the terminal. According to the present invention, both impedances of the first and third replica buffers are adjusted based on the potential of the terminal, and therefore an adjustment error of one of the replica buffers is not superimposed with an adjustment error of the other replica buffer.

### BACKGROUND OF THE INVENTION

1. Field of the Invention

The present invention relates to a semiconductor device and a circuit board having the semiconductor device mounted thereon, and more particularly relates to a semiconductor device capable of adjusting an impedance of an output buffer and a circuit board having the semiconductor device mounted thereon.

2. Description of Related Art

In recent years, a data transfer between semiconductor devices (such as between a CPU and a memory device) requires a very high data-transfer rate. To achieve this, an amplitude of an input/output signal is made increasingly smaller. When an input/output signal has a small amplitude, the required precision of an impedance of an output buffer becomes very severe.

The impedance of an output buffer not only fluctuates according to a processing condition at a time of manufacturing but also is influenced by an ambient temperature and a fluctuation of a power source voltage when the output buffer is actually used. Therefore, when the output buffer is required to have a high precision of an impedance, an output buffer having an impedance adjusting function is employed. An impedance of such an output buffer is generally adjusted by using an output-impedance adjusting circuit called “calibration circuit”. The output-impedance adjusting circuit adjusts an impedance of a replica buffer by referring to a potential of a calibration terminal, and reflects the adjustment result to the output buffer (see Japanese Patent Application Laid-open Nos. H11-340810 and 2008-48361).

The output-impedance adjusting circuit described in Japanese Patent Application Laid-open No. H11-340810 employs a system of generating plural constant currents that become a reference by a current mirror circuit connected to a calibration terminal, thereby simultaneously adjusting an impedance of a replica buffer at a pull-up side and an impedance of a replica buffer at a pull-down side by using these constant currents.

FIG. 11 is a diagram created by the present inventor by adding some parts to FIG. 5 of Japanese Patent Application Laid-open No. H11-340810.

As shown in FIG. 11, a current mirror circuit CM supplies a current which is the same as a current I_{ZQ} flowing to an external resistor RQ connected to a calibration terminal ZQ, to a replica buffer RPU for a pull-up circuit and to a replica buffer RPD for a pull-down circuit. Accordingly, both an impedance of the replica buffer RPU for the pull-up circuit and an impedance of the replica buffer RPD for the pull-down circuit can be matched with an impedance of the external resistor RQ.

However, the output-impedance adjusting circuit described in Japanese Patent Application Laid-open No. H11-340810 employs a current mirror circuit as a constant-current source. Therefore, source-drain voltages of transistors 25 to 29 constituting the current mirror circuit become difficult to be set at a voltage at which the current mirror circuit can perform a stable operation, when an operation current of the semiconductor device becomes low. As a result, fluctuations occur in a current value of the current I_{ZQ} and an impedance adjustment error attributable to the variations of the current value occurs.

On the other hand, the output-impedance adjusting circuit described in Japanese Patent Application Laid-open No. 2008-48361 employs a system of adjusting an impedance of a replica buffer 110 at a pull-up side connected to a calibration terminal and then adjusting an impedance of a replica buffer 130 at a pull-down side connected in series to a replica buffer 120. When the impedance of the replica buffer 130 is adjusted, this adjustment is performed in a state that an adjusted impedance of the replica buffer 110 is reflected to the replica buffer 120. In this manner, because the output-impedance adjusting circuit described in Japanese Patent Application Laid-open No. 2008-48361 does not use a current mirror circuit, the problem in Japanese Patent Application Laid-open No. H11-340810 described above does not occur.

However, according to the impedance adjustment using the output-impedance adjusting circuit described in Japanese Patent Application Laid-open No. 2008-48361, the impedance of the replica buffer 130 at the pull-down side is adjusted such that the impedance matches the adjusted impedance of the replica buffer 110 by using the adjusted impedance of the replica buffer 110 as a reference. Therefore, an impedance adjustment error of the replica buffer 110 at the pull-up side is superimposed with the impedance adjustment error of the replica buffer 130 at the pull-down side, and the impedance adjustment error at the pull-down side becomes large.

The present inventor has found that the adjustment error of the impedance at the pull-up side in Japanese Patent Application Laid-open No. 2008-48361 is partly attributable to a fact that the impedance of the replica buffer 110 that should be basically adjusted to match the impedance of the external resistor is adjusted based on an impedance higher or lower than the impedance of the external resistor due to fluctuations of processing conditions of a comparator 151 and the like at a time of manufacturing. The influence of such fluctuations of the processing conditions also naturally occurs in a circuit (such as a comparator 152) that adjusts the impedance of the replica buffer 130 at the pull-down side. Therefore, for example, when the impedance adjustment error due to the fluctuations of the process conditions and the like gives the same influence at the pull-up side and the pull-down side (for example, an influence that an actual reference value becomes higher than an original reference value), the impedance of the replica buffer 130 is adjusted based on an impedance much higher than the impedance of the replica buffer 110 adjusted based on the impedance higher than the impedance of the external resistor. Consequently, there has been a risk that the impedance of the replica buffer 130 at the pull-down side is greatly deviated from the impedance of the external resistor.

In order to prevent the impedance of the replica buffer at the pull-down side from being greatly deviated from the impedance of the external resistor as described above, it suffices that the impedance of the replica buffer at the pull-up side and that of the replica buffer at the pull-down side are adjusted based on the impedance of the external resistor. The present invention has been achieved based on the above technical findings.

### SUMMARY

In one embodiment, there is provided a semiconductor device that includes: a first replica buffer connected to a first terminal; a first impedance-adjusting circuit that compares a potential of the first terminal with a predetermined potential, and changes an impedance of the first replica buffer according to a comparison result; a second replica buffer having a substantially same impedance as that of the first replica buffer; a third replica buffer connected in series to the second replica buffer; and a second impedance-adjusting circuit that compares a potential of a connection node of the second replica buffer and the third replica buffer with a potential of the first terminal, and changes an impedance of the third replica buffer according to a comparison result.

In another embodiment, there is provided a circuit board that includes: a substrate; the semiconductor device mounted on the substrate; and an external resistor that is mounted on the substrate and is connected to the first terminal of the semiconductor device.

In still another embodiment, there is provided a device comprising: a first terminal; a first driving circuit coupled to the first terminal, having a first adjustable impedance and driving, when activated, the first terminal to a first logic level with a first adjusted impedance; a second driving circuit coupled to the first terminal, having a second adjustable impedance and driving, when activated, the first terminal to a second logic level with a second adjusted impedance; a first control circuit coupled to the first and second driving circuit and changing each of the first and the second adjustable impedance to approach to a reference impedance, the first control circuit terminating changing the each of the first and the second adjustable impedance when the each of the first and the second adjustable impedance has reached or crossed the reference impedance from a first adjusting impedance higher than the reference impedance in response to a third logic level of a selection signal and terminating changing the each of the first and second adjustable impedance when the each of the first and the second adjustable impedance has reached or crossed from a second adjusting impedance lower than the reference impedance in response to a fourth logic level of the selection signal; and a second control circuit generating the selection signal.

According to the present invention, impedances of the first and third replica buffers are adjusted based on a potential of the first terminal, and therefore an adjustment error at the pull-up side is not superimposed with an adjustment error at the pull-down side, unlike in conventional impedance adjusting circuits. In addition, because a current mirror circuit is not used for a current source, there is no risk of occurrence of an impedance adjustment error attributable to fluctuations of a current value due to a reduced power source voltage.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a configuration of a semiconductor device according to an embodiment of the present invention;

FIG. 2 is a block diagram showing a configuration of an output-impedance adjusting circuit 100;

FIG. 3 is a circuit diagram of a replica buffer 110;

FIG. 4 is a circuit diagram of a replica buffer 130;

FIG. 5 is a block diagram showing a configuration of a data input/output unit 75;

FIG. 6 is a circuit diagram of an output-impedance control circuit 230;

FIG. 7 is a circuit diagram of an output buffer 210;

FIG. 8 is a circuit diagram showing an example in which plural output buffers 210 are connected to each other in parallel for a same data terminal DQ;

FIG. 9 is a timing diagram for explaining an example of an operation the semiconductor device 10 according to the present embodiment;

FIG. 10 is a timing diagram for explaining another example of an operation the semiconductor device 10 according to the present embodiment; and

FIG. 11 is a diagram created by the present inventor by adding some parts to FIG. 5 of Japanese Patent Application Laid-open No. H11-340810.

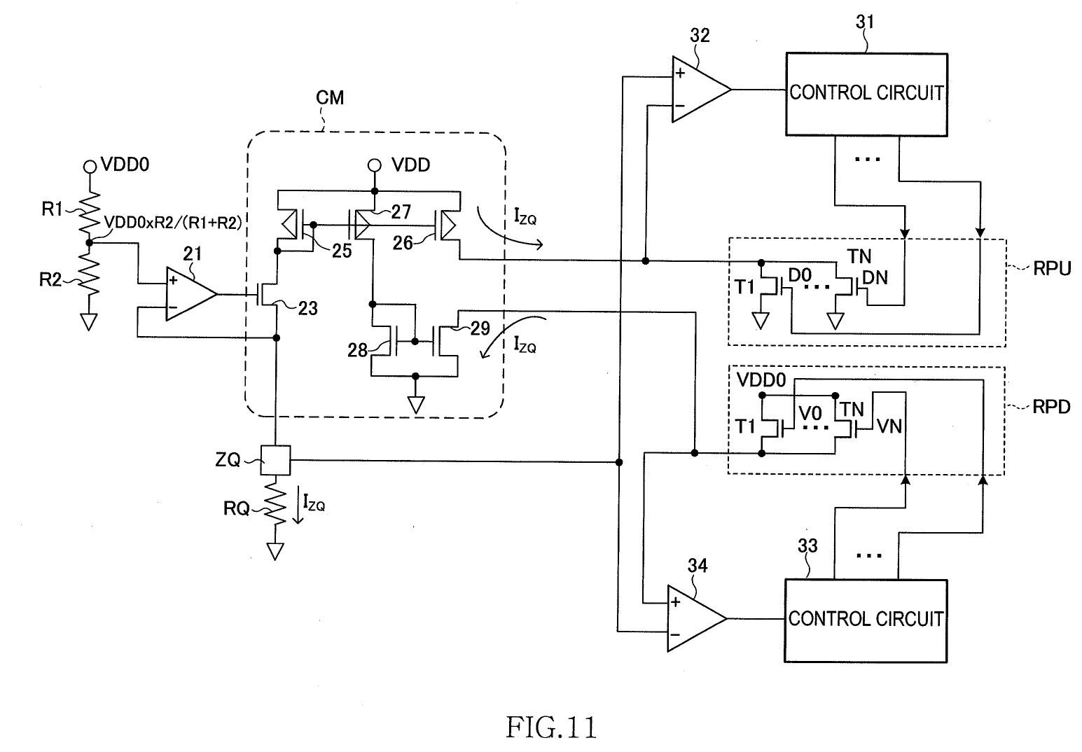

### DETAILED DESCRIPTION OF THE EMBODIMENTS

Preferred embodiments of the present invention will be explained below in detail with reference to the accompanying drawings.

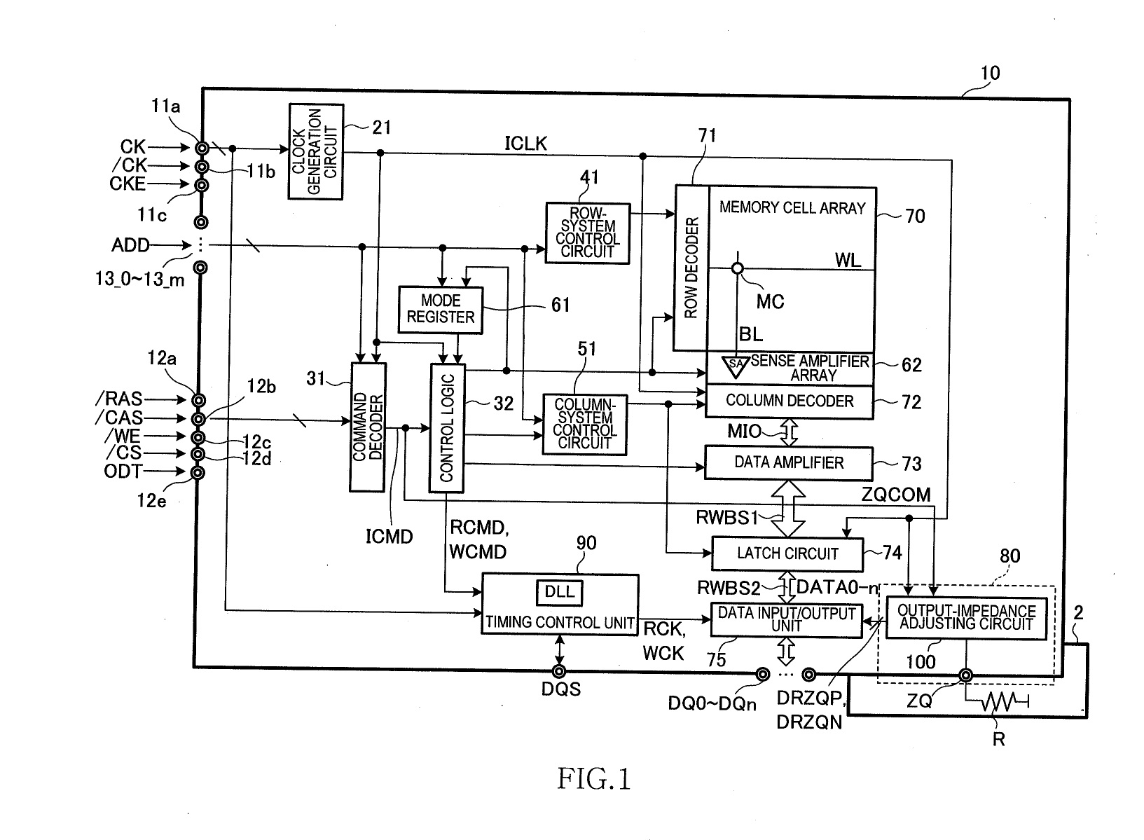

FIG. 1 is a block diagram showing a configuration of a semiconductor device according to an embodiment of the present invention.

As shown in FIG. 1, a semiconductor device 10 according to the present embodiment includes clock pads 11a and 11b, a clock enable pad 11c, command pads 12a to 12e, address pads 13_0 to 13_m, data pads DQ0 to DQn, a data strobe pad DQS, and a calibration pad ZQ as external terminals. Although the semiconductor device 10 also includes a power source pad or the like, these parts are not shown in FIG. 1.

The clock pads 11a and 11b are supplied with external clock signals CK and /CK, respectively. The clock enable pad 11c is supplied with a clock enable signal CKE. The external clock signals CK, /CK and the clock enable signal CKE supplied are supplied to a clock generation circuit 21. In the present specification, signals attached with “/” at heads of signal names indicate inversion signals of corresponding signals or low active signals. Therefore, the external clock signals CK, /CK are mutually complementary signals. The clock generation circuit 21 generates an internal clock signal ICLK. The internal clock signal ICLK generated is supplied to various circuit blocks of the semiconductor device 10.

The command pads 12a to 12e are supplied with a row-address strobe signal /RAS, a column-address strobe signal /CAS, a write enable signal /WE, a chip select signal /CS, and an on-die termination signal ODT, respectively. These command signals are supplied to a command decoder 31.

The address pads 13_0 to 13_m are supplied with address signals ADD. The address signals ADD supplied are supplied to a row-system control circuit 41, a column-system control circuit 51, a command decoder 31, and a mode register 61 via an address input circuit (not shown). More specifically, in a normal operation mode, a row address among the address signals ADD is supplied to the row-system control circuit 41, and a column address is supplied to the column-system control circuit 51. When it is entered in a mode register set, the address signals ADD are supplied to the mode register 61, thereby updating a content of the mode register 61.

The command decoder 31 is a circuit that generates various internal commands ICMD by holding a part of a command signal and an address signal, decoding and counting synchronously with the internal clock signal ICLK. The internal commands ICMD generated are supplied to various circuit blocks of the semiconductor device 10 via a control logic 32.

The control logic 32 controls operations of various circuit blocks synchronously with the internal clock signal ICLK according to the internal commands ICMD supplied from the command decoder 31 and an output of the mode register 61.

An output of the row-system control circuit 41 is supplied to a row decoder 71. The row decoder 71 is a circuit selecting any word line WL included in a memory cell array 70. Plural word lines WL and plural bit lines BL cross each other in the memory cell array 70. Memory cells MC are arranged at intersections of these lines (FIG. 1 only shows one word line WL, one bit line BL, and one memory cell MC). Bit lines BL are connected to corresponding sense amplifiers SA in a sense amplifier array 62.

An output of the column-system control circuit 51 is supplied to a column decoder 72. The column decoder 72 is a circuit selecting any sense amplifier circuit SA included in the sense amplifier array 62. A sense amplifier SA selected by the column decoder 72 is connected to a data amplifier 73 via a main I/O line MIO. In a read operation, the data amplifier 73 further amplifies read data amplified by the sense amplifier SA, and supplies the amplified data to a latch circuit 74 via a read-write bus RWBS1. On the other hand, in a write operation, the data amplifier 73 amplifies write data supplied from the latch circuit 74 via the read-write bus RWBS1, and supplies the amplified write data to the memory cell array 70.

The latch circuit 74 is a parallel-serial conversion circuit that parallel-serial converts input/output data between the data amplifier 73 and a data input/output unit 75.

A timing control unit 90 includes a DLL (Delay Locked Loop) circuit that controls an input/output timing of data. In a read operation, the timing control unit 90 outputs to the data input/output unit 75 a read timing signal RCK for controlling a read timing of data in the data input/output unit 75 according to a read command RCMD supplied from the control logic 32 and the external clock signals CK, /CK, and at the same time, outputs a data strobe signal to outside via the data strobe pad DQS. On the other hand, in a write operation, the timing control unit 90 supplies to the data input/output unit 75 a write timing signal WCK for controlling a fetching timing of write data in the data input/output unit 75 according to a write command WCMD supplied from the control logic 32, the external clock signals CK, /CK, and a data strobe signal supplied from outside via the data strobe pad DQS.

An output-impedance adjusting unit 80 includes an output-impedance adjusting circuit 100 and the calibration terminal ZQ as a first terminal. The output-impedance adjusting circuit 100 receives an impedance adjusting command ZQCOM as an internal command supplied from the command decoder 31 and the internal clock signal ICLK supplied from the clock generation circuit 21, and supplies a pull-up impedance adjusting signal DRZQP and a pull-down impedance adjusting signal DRZQN to the data input/output unit 75. An external resister R having a desired resistance value is connected to the calibration terminal ZQ. An external resistor R is an element different from the semiconductor device 10, and is mounted on a substrate 2. The substrate 2 is a circuit board on which the semiconductor device 10 is mounted. Details of the output-impedance adjusting circuit 100 are described later.

The data input/output unit 75 outputs plural read data DATA0 to DATAn supplied from a read-write bus RWBS2 configured by plural wirings, to outside (at a read time) via plural data pads DQ0 to DQn, or outputs the plural read data DATA0 to DATAn input via the plural data pads DQ0 to DQn, to the read-write bus RWBS2 (at a write time). Details of the data input/output unit 75 are described later.

The overall configuration of the semiconductor device 10 is as described above. A configuration of the output-impedance adjusting circuit 100 is explained next in detail.

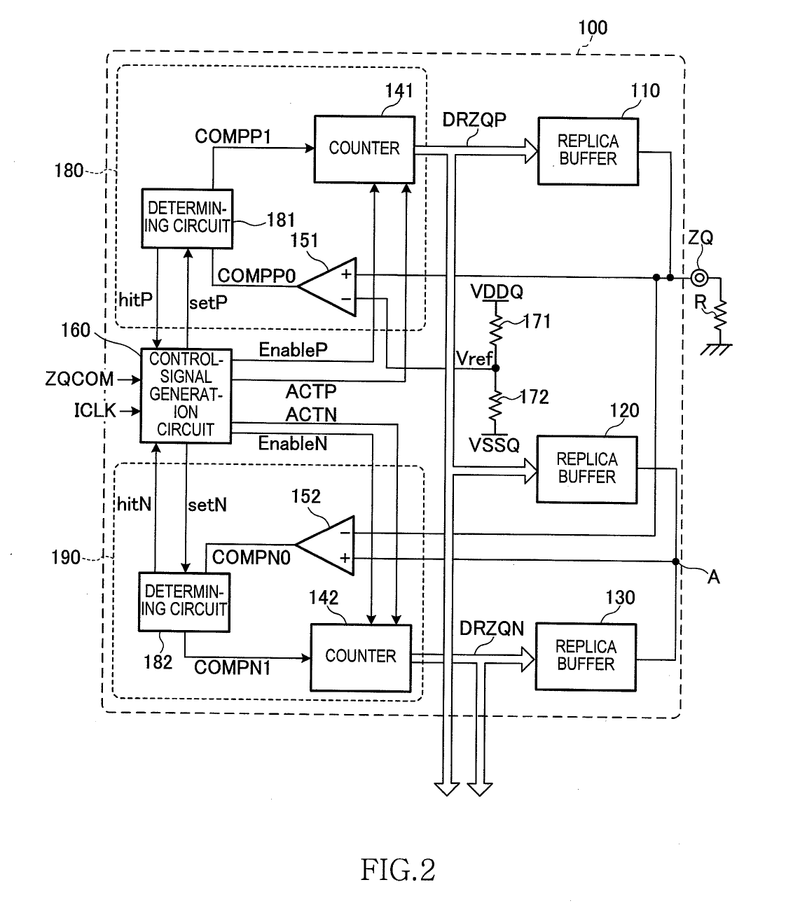

FIG. 2 is a block diagram showing a configuration of the output-impedance adjusting circuit 100.

As shown in FIG. 2, the output-impedance adjusting circuit 100 includes a pull-up impedance adjusting circuit 180 adjusting impedances of the replica buffers 110 and 120, a pull-down impedance adjusting circuit 190 adjusting an impedance of the replica buffer 130, and a control-signal generation circuit 160 that controls operations of the impedance adjusting circuits 180 and 190.

The replica buffers 110, 120, and 130 have circuits which are the same as a part of an output buffer described later. Output impedances are adjusted by using the replica buffers 110, 120, and 130. A result of this adjustment is reflected to the output buffer, thereby setting an impedance of the output buffer at a desired value. This is a role of the output-impedance adjusting circuit 100.

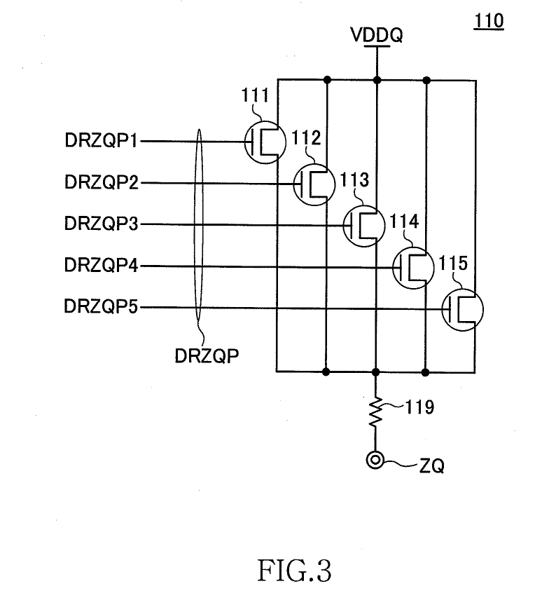

FIG. 3 is a circuit diagram of the replica buffer 110.

The replica buffer 110 is configured by five P-channel MOS transistors 111 to 115 connected in parallel to a power source wiring VDDQ, and a resistor 119 of which one end is connected to drains of these transistors. The other end of the resistor 119 is connected to the calibration terminal ZQ. The replica buffer 110 has only a pull-up function, and does not have a pull-down function. The power source wiring VDDQ is supplied with a power source potential at a high-order side.

Corresponding bits of the pull-up impedance adjusting signal DRZQP are supplied to gates of the transistors 111 to 115, respectively. Accordingly, five transistors included in the replica buffer 110 can be individually on/off controlled.

A parallel circuit of the transistors included in the replica buffer 110 is designed to have a predetermined impedance (120Ω, for example) during conduction. However, an on resistance of a transistor fluctuates based on a manufacturing condition and varies according to an environmental temperature and a power source voltage during an operation. Therefore, a desired impedance is not necessarily obtained. Consequently, to actually set the impedance at 120Ω, the number of transistors to be turned on needs to be adjusted. The parallel circuit including plural transistors is used for this purpose.

To perform impedance adjustment finely as well as in a wide range, it is preferable that W/L ratios (gate width/gate length ratios) of the plural transistors constituting the parallel circuit are made mutually different. Putting a weight of the power of two is particularly preferable. Considering this point, in the present embodiment, W/L ratios of the transistors 112 to 115 are set at 2 WLp, 4 WLp, 8 WLp, and 16 WLp, respectively when a W/L ratio of the transistor 111 is 1 WLp.

With this arrangement, the on resistance of the parallel circuit can be fixed at substantially 120Ω regardless of the fluctuation due to a manufacturing condition and a temperature change, by suitably selecting a transistor to be turned on by the pull-up impedance adjusting signal DRZQP.

The resistance value of the resistor 119 is set at 120Ω, for example. Accordingly, when the parallel circuit configured by the transistors 111 to 115 becomes in an on state, an impedance of the replica buffer 110 from a viewpoint of the calibration terminal ZQ becomes 240Ω. A tungsten (W) resistor, for example, can be used for the resistor 119.

The replica buffer 120 also has the same circuit configuration as that of the replica buffer 110 shown in FIG. 3 except that the other end of the resistor 119 is connected to a connection node A. Therefore, corresponding bits of the pull-up impedance adjusting signal DRZQP are supplied to gates of five transistors included in the replica buffer 120.

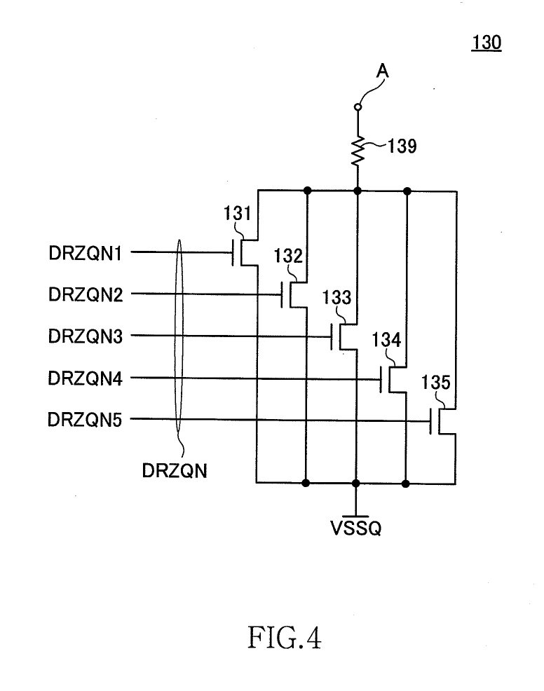

FIG. 4 is a circuit diagram of the replica buffer 130.

As shown in FIG. 4, the replica buffer 130 is configured by five N-channel MOS transistors 131 to 135 connected in parallel to a ground wiring VSSQ, and a resistor 139 of which one end is connected to these transistors. The other end of the resistor 139 is connected to the connection node A. The replica buffer 130 has only a pull-down function, and does not have a pull-up function. The ground wiring VSSQ is a power source wiring to which a power source potential (a ground potential) at a low-order side is supplied.

Corresponding bits of the pull-down impedance adjusting signal DRZQN are supplied to gates of the transistors 131 to 135 respectively. Accordingly, five transistors included in the replica buffer 130 can be individually on/off controlled.

A parallel circuit of the transistors included in the replica buffer 130 is also designed to have a resistance value 120Ω, for example, during conduction. The resistance value of the resistor 139 is also designed at 120Ω, for example. Accordingly, when a parallel circuit including the transistors 131 to 135 becomes in an on state, an impedance of the replica buffer 130 from a viewpoint of the connection node A becomes 240Ω similar to the impedances of the replica buffers 110 and 120.

Regarding the transistors 131 to 135, it is also particularly preferable to put a weight of the power of two to their W/L in a similar manner to the W/L of the transistors 111 to 115. Specifically, W/L ratios of the transistors 132 to 135 are set at 2 WLn, 4 WLn, 8 WLn, and 16 WLn, respectively when a W/L ratio of the transistor 131 is 1 WLn.

Referring back to FIG. 2, the output-impedance adjusting circuit 100 includes the pull-up impedance adjusting circuit 180 adjusting impedances of the replica buffers 110 and 120, and the pull-down impedance adjusting circuit 190 adjusting an impedance of the replica buffer 130.

The pull-up impedance adjusting circuit 180 includes a counter 141 that generates the pull-up impedance adjusting signal DRZQP, a determining circuit 181 that causes the counter 141 to count up or count down a count value by supplying a determination signal COMPP1 to the counter 141, and the comparator 151 that supplies a determination signal COMPP0 to the determining circuit 181. The comparator 151 is a circuit that compares an output potential of the replica buffer 110 (a potential of the calibration terminal ZQ) with a reference potential Vref. Specifically, a non-inverted input terminal (+) of the comparator 151 is connected to the calibration terminal ZQ, and an inverted input terminal (−) is connected to a connection node of resistors 171 and 172. The resistors 171 and 172 are connected in series between the power source wiring VDDQ and the ground wiring VSSQ, and a potential of the connection node becomes the reference potential Vref. Therefore, the comparator 151 sets the determination signal COMPP0 as an output of the comparator 151 at a high level when the potential of the calibration terminal ZQ is higher than the reference potential Vref. On the other hand, the comparator 151 sets the determination signal COMPP0 as an output of the comparator 151 at a low level when the potential of the calibration terminal ZQ is lower than the reference potential Vref.

Similarly, the pull-down impedance adjusting circuit 190 includes a counter 142 that generates the pull-down impedance adjusting signal DRZQN, a determining circuit 182 that causes the counter 142 to count up or count down a count value by supplying a determination signal COMPN1 to the counter 142, and the comparator 152 that supplies a determination signal COMPN0 to the determining circuit 182. The comparator 152 is a circuit that compares an output potential of the replica buffer 110 (a potential of the calibration terminal ZQ) with output potentials of the replica buffers 120 and 130 (a potential of the connection node A). Specifically, a non-inverted input terminal (+) of the comparator 152 is connected to the connection node A, and an inverted input terminal (−) is connected to the calibration terminal ZQ. As described above, the connection node A is a connection point between the replica buffer 120 and the replica buffer 130. Therefore, the comparator 152 sets the determination signal COMPN0 as an output of the comparator 152 at a high level when the potential of the connection node A is higher than that of the calibration terminal ZQ. On the other hand, the comparator 152 sets the determination signal COMPN0 as an output of the comparator 152 at a low level when the potential of the connection node A is lower than that of the calibration terminal ZQ.

Operations of these impedance adjusting circuits 180 and 190 are controlled by the control-signal generation circuit 160. The control-signal generation circuit 160 is started based on an impedance adjusting command ZQCOM supplied from the command decoder 31, and an operation of the control-signal generation circuit 160 is performed synchronously with the internal clock signal ICLK supplied from the clock generation circuit 21. When the control-signal generation circuit 160 is started, a sampling clock ACTP and an adjustment enable signal EnableP are supplied to the counter 141, and a sampling clock ACTN and an adjustment enable signal EnableN are supplied to the counter 142. A set signal setP is supplied to the determining circuit 181, and a set signal setN is supplied to the determining circuit 182. Determination signals hitP and hitN output from the determining circuits 181 and 182, respectively are supplied to the control-signal generation circuit 160.

Specifically, upon receiving the impedance adjusting command ZQCOM, the control-signal generation circuit 160 activates the sampling clock ACTP and the adjustment enable signal EnableP, and supplies the set signal setP to the determining circuit 181, synchronously with the internal clock signal ICLK. Further, when the determination signal hitP is inactivated, the control-signal generation circuit 160 inactivates the sampling clock ACTP and the adjustment enable signal EnableP, activates the sampling clock ACTN and the adjustment enable signal EnableN, synchronously with the internal clock signal ICLK, and supplies the set signal setN to the determining circuit 182. When the determination signal hitN from the determining circuit 182 is inactivated, the control-signal generation circuit 160 inactivates the sampling clock ACTN and the adjustment enable signal EnableN. The control-signal generation circuit 160 can inactivate the sampling clocks ACTP and ACTN and the adjustment enable signals EnableP and EnableN according to a lapse of a predetermined time after receiving the impedance adjusting command ZQCOM, in addition to when the determination signals hitP and hitN supplied from the determining circuits 181 and 182 are inactivated.

Preferably, the sampling clocks ACTP and ACTN are obtained by frequency-dividing the internal clock signal ICLK at a predetermined frequency-dividing ratio. Although FIG. 2 shows a structure that the control-signal generation circuit 160 supplies separate sampling clocks ACTP and ACTN to the counters 141 and 142, the control-signal generation circuit 160 can be configured to supply a common sampling clock. to these counters 141 and 142.

As described above, the pull-up impedance adjusting circuit 180 includes the comparator 151, the determining circuit 181, and the counter 141. The comparator 151 compares a potential of the calibration terminal ZQ with the reference potential Vref. When the former is higher, the determination signal COMPP0 is set at a high level. When the latter is higher, the determination signal COMPP0 is set at a low level. The determining circuit 181 is set according to activation of the set signal setP supplied from the control-signal generation circuit 160, and sets the determination signal hitP at a high level as an active level. The determining circuit 181 outputs to the counter 141 the determination signal COMPP0 supplied from the comparator 151 as COMPP1. When the determination signal COMPP0 shifts in a predetermined pattern, for example, when the determination signal COMPP0 shifts as high level→low level→high level, the determining circuit 181 sets the determination signal hitP at a low level as an inactive level.

The counter 141 is activated during a period while the adjustment enable signal EnableP supplied from the control-signal generation circuit 160 is at an active level. When the determination signal COMPP1 supplied from the determining circuit 181 is at a high level, the counter 141 counts up a count value synchronously with the sampling clock ACTP. When the determination signal COMPP1 is at a low level, the counter 141 counts down the count value synchronously with the sampling clock ACTP. The count value of the counter 141 is supplied as the pull-up impedance adjusting signal DRZQP, to the replica buffers 110 and 120 as first and second buffer circuits and to the data input/output unit 75.

Similarly, the pull-up impedance adjusting circuit 190 includes the comparator 152, the determining circuit 182, and the counter 142. The comparator 152 compares a potential of the connection node A with a potential of the calibration terminal ZQ. When the former is higher, the determination signal COMPN0 is set at a high level. When the latter is higher, the determination signal COMPN0 is set at a low level. The determining circuit 182 is set according to activation of the set signal setN supplied from the control-signal generation circuit 160, and sets the determination signal hitN at a high level as an active level. The determining circuit 182 outputs to the counter 142 the determination signal COMPN0 supplied from the comparator 152 as COMPN1. When the determination signal COMPN0 shifts in a predetermined pattern, for example, when the determination signal COMPN0 shifts as low level→high level→low level, the determining circuit 182 sets the determination signal hitN at a low level as an inactive level.

The counter 142 is activated during a period while the adjustment enable signal EnableN supplied from the control-signal generation circuit 160 is at an active level. When the determination signal COMPN1 supplied from the determining circuit 182 is at a high level, the counter 142 counts up a count value synchronously with the sampling clock ACTN. When the determination signal COMPN1 is at a low level, the counter 142 counts down the count value synchronously with the sampling clock ACTN. The count value of the counter 142 is supplied as the pull-down impedance adjusting signal DRZQN, to the replica buffer 130 as a third buffer circuit and to the data input/output unit 75.

The configuration of the output-impedance adjusting circuit 100 is as described above. Details of the operation of the output-impedance adjusting circuit 100 are described later.

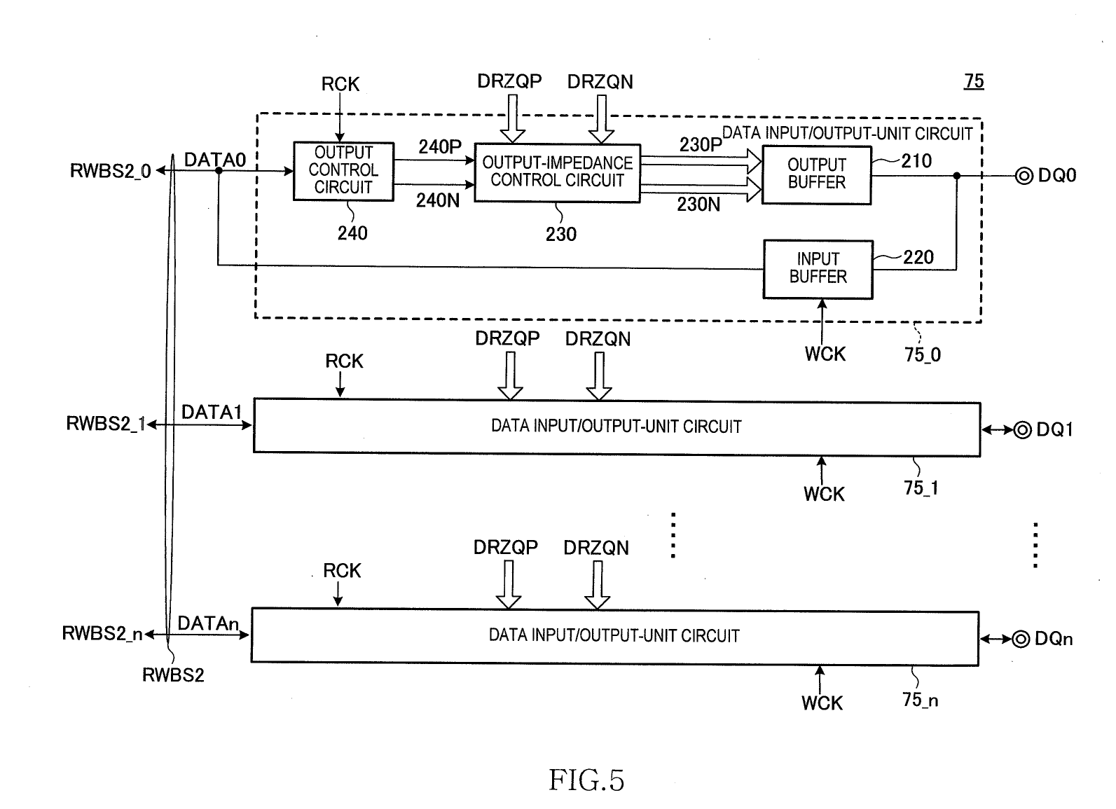

FIG. 5 is a block diagram showing a configuration of the data input/output unit 75.

As shown in FIG. 5, the data input/output unit 75 includes plural data input/output-unit circuits 75_0 to 75_n provided corresponding to the data terminals DQ0 to DQn, respectively. These data input/output-unit circuits 75_0 to 75_n are commonly supplied with the read timing signal RCK and the write timing signal WCK from the timing control unit 90, and are also commonly supplied with the pull-up impedance adjusting signal DRZQP and the pull-down impedance adjusting signal DRZQN from the output-impedance adjusting circuit 100. The data input/output-unit circuits 75_0 to 75_n are connected to corresponding read/write wirings RWBS2_0 to RWBS2_n, respectively. The read/write wirings RWBS2_0 to RWBS2_n configure the read-write bus RWBS2 shown in FIG. 1.

Each of the data input/output-unit circuits 75_0 to 75_n includes an output control circuit 240, an output-impedance control circuit 230, an output buffer 210, and an input buffer 220. As shown in FIG. 5, the data terminals DQ0 to DQn are connected to the output buffer 210 and the input buffer 220 in the corresponding data input/output-unit circuits 75_0 to 75_n, and the read/write wirings RWBS2_0 to RWBS2_n are connected to the output control circuit 240 and the input buffer 220 in the corresponding data input/output-unit circuits 75_0 to 75_n. Accordingly, in a write operation, write data input to the data terminals DQ0 to DQn are supplied to the read/write wirings RWBS2_0 to RWBS2_n via the input buffers 220. In this case, timings when the write data are supplied to the read/write wirings RWBS2_0 to RWBS2_n are controlled by the write timing signal WCK supplied to the input buffer 220. In a read operation, read data output to the read/write wirings RWBS2_0 to RWBS2_n are supplied to the data terminals DQ0 to DQn via the output control circuit 240, the output-impedance control circuit 230, and the output buffer 210. In this case, a timing when the read data is supplied to the output-impedance control circuit 230 is controlled by the read timing signal RCK supplied to the output control circuit 240.

The output control circuit 240 inverts the read data DATA supplied from a corresponding read/write wiring according to activation of the read timing signal RCK, and supplies the inverted data as read data 240P and 240N to the output-impedance control circuit 230.

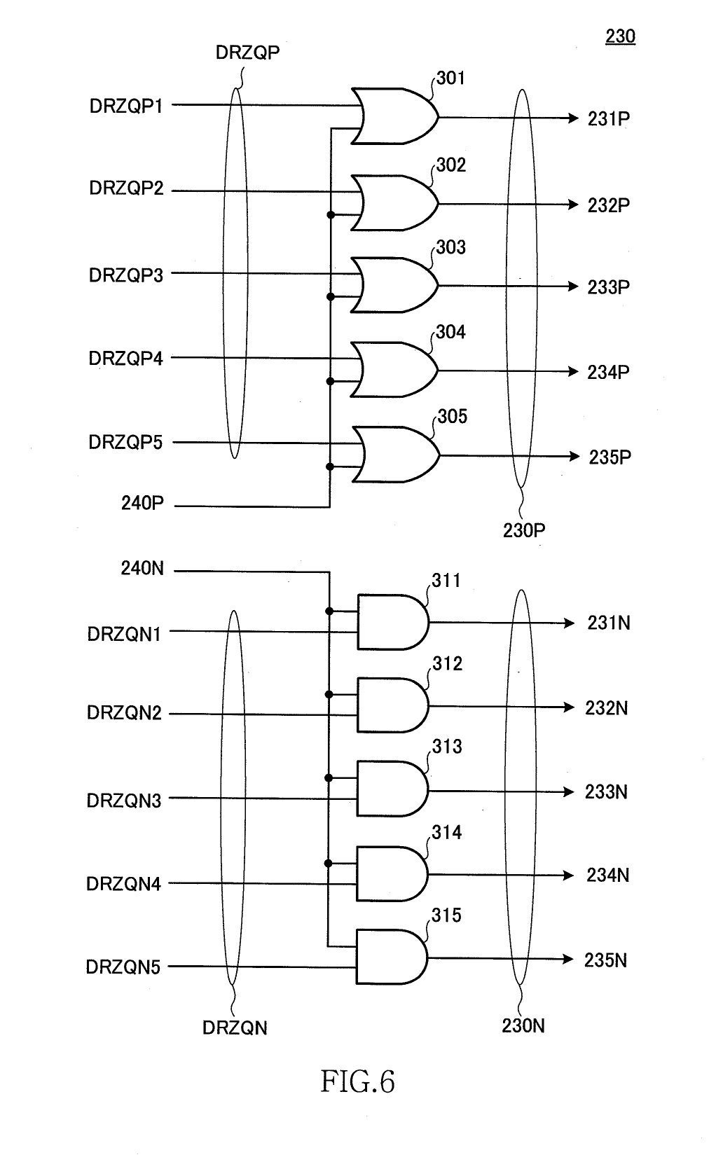

FIG. 6 is a circuit diagram of the output-impedance control circuit 230.

As shown in FIG. 6, the output-impedance control circuit 230 is configured by five OR circuits 301 to 305 and five AND circuits 311 to 315. The OR circuits 301 to 305 are commonly supplied with the read data 240P from the output control circuit 240, and are also supplied with bits DRZQP1 to DRZQP5, respectively of the pull-up impedance adjusting signal DRZQP from the output-impedance adjusting circuit 100. On the other hand, the AND circuits 311 to 315 are commonly supplied with the read data 240N from the output control circuit 240, and are also supplied with bits DRZQN1 to DRZQN5, respectively of the pull-down impedance adjusting signal DRZQN.

The read data 240P and 240N as outputs of the output control circuit 240 are controlled according to a logic value or the like of data to be output from corresponding data terminals DQ0 to DQn. Specifically, in outputting high-level signals from the corresponding data terminals DQ0 to DQn, the read data 240P and 240N are set at low levels. When low-level signals are output from the corresponding data terminals DQ0 to DQn, the read data 240P and 240N are set at high levels. In using an ODT (On Die Termination) function using the output buffer 210 as a termination resistor, the read data 240P is set at a low level, and the read data 240N is set at a high level.

Operation signals 231P to 235P (=230P) as outputs of the OR circuits 301 to 305, and operation signals 231N to 235N (=230N) as outputs of the AND circuits 311 to 315 are supplied to the output buffer 210 as shown in FIG. 5.

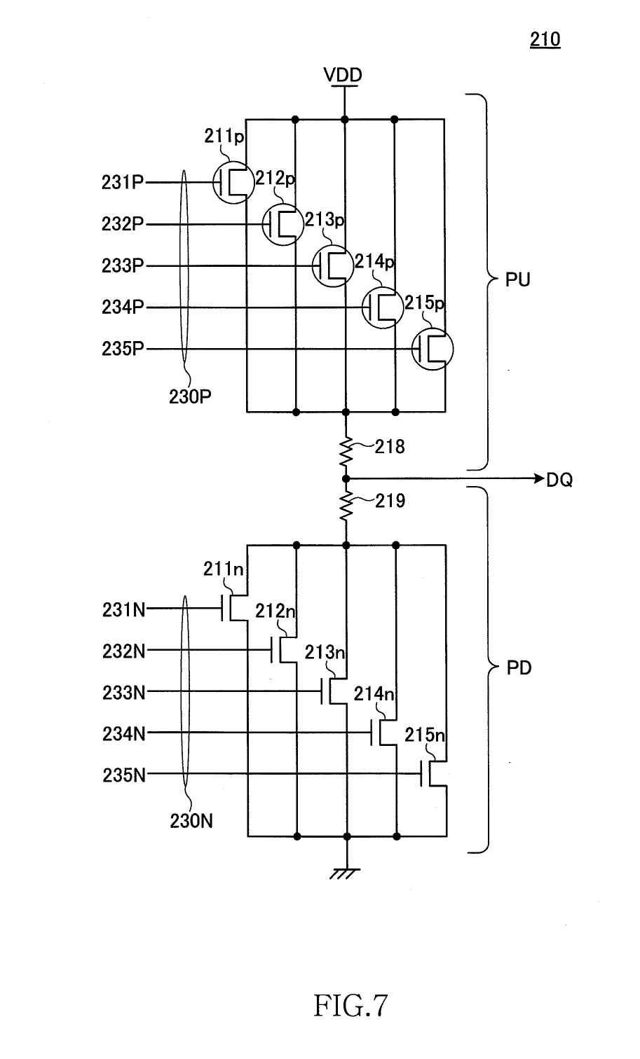

FIG. 7 is a circuit diagram of the output buffer 210.

As shown in FIG. 7, the output buffer 210 includes five P-channel MOS transistors 211p to 215p connected in parallel, and five N-channel MOS transistors 211n to 215n connected in parallel. Resistors 218 and 219 are connected in series between each of the transistors 211p to 215p and a corresponding one of the transistors 211n to 215n, and each connection point between the resistor 218 and the resistor 219 is connected to a corresponding one of the data terminals DQ0 to DQn.

Gates of the transistors 211p to 215p are supplied with five operation signals 231P to 235P, respectively constituting the operation signal 230P. Gates of the transistors 211n to 215n are supplied with five operation signals 231N to 235N, respectively constituting the operation signal 230N. Accordingly, ten transistors included in the output buffer 210 are individually on/off controlled by ten operation signals 231P to 235P and 231N to 235N. The operation signals 231P to 235P are a group of signals constituting the operation signal 230P, and the operation signals 231N to 235N are a group of signals constituting the operation signal 230N.

In the output buffer 210, a pull-up circuit PU including the P-channel MOS transistors 211p to 215p and the resistor 218 has a circuit configuration which is the same as that of the replica buffer 110 (120) shown in FIG. 3. A pull-down circuit PD including the N-channel MOS transistors 211n to 215n and the resistor 219 has a circuit configuration which is the same as that of the replica buffer 130 shown in FIG. 4.

Therefore, a parallel circuit including the transistors 211p to 215p and a parallel circuit including the transistors 211n to 215n are respectively designed to have a resistance value 120Ω, for example, during conduction. The resistance values of the resistors 218 and 219 are designed at 120Ω, for example, respectively. Accordingly, when one of the parallel circuit including the transistors 211p to 215p and the parallel circuit including the transistors 211n to 215n is in an on state, an impedance of the output buffer 210 from a viewpoint of a corresponding one of the data terminals DQ0 to DQn becomes 240Ω.

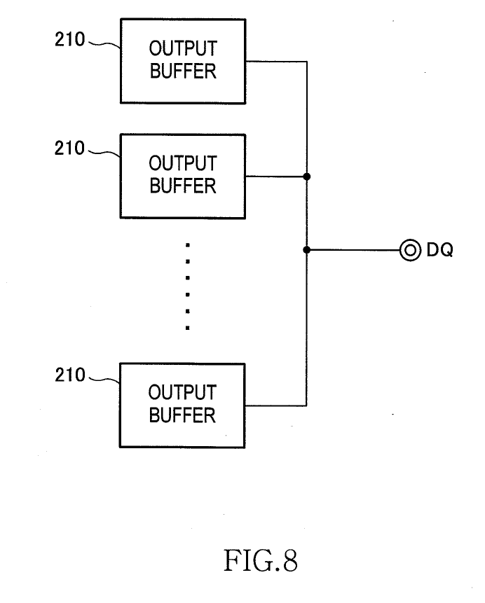

In an actual semiconductor device, plural output buffers 210 are provided in parallel for one data terminal DQ as shown in FIG. 8. An output impedance can be selected according to the number of output buffers to be used. That is, when an impedance of one output buffer is X, an output impedance can be set at X/Y by using Y output buffers in parallel.

An operation of the semiconductor device 10 according to the present embodiment is explained next.

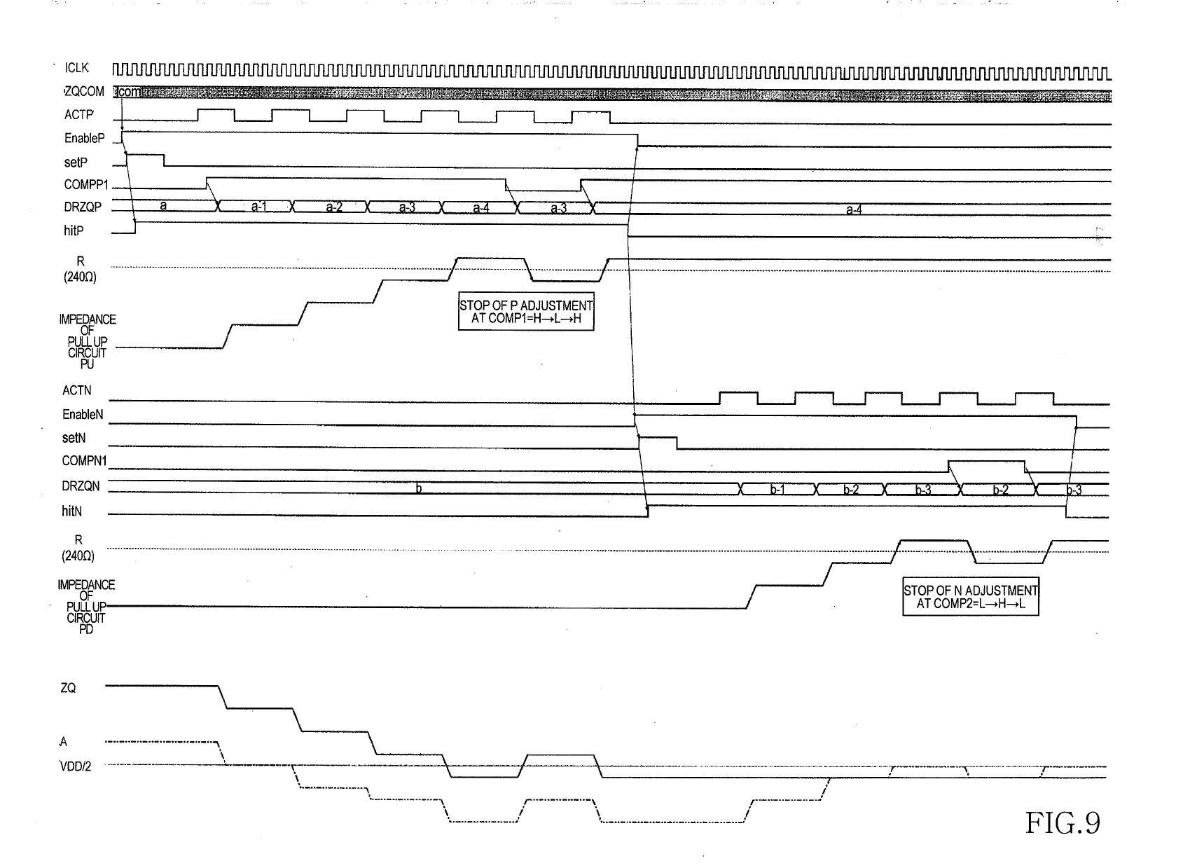

FIG. 9 is a timing diagram for explaining an example of an operation the semiconductor device 10 according to the present embodiment.

In the example shown in FIG. 9, when the impedance adjusting command ZQCOM is activated, the control-signal generation circuit 160 activates the adjustment enable signal EnableP at a high level, and generates the sampling clock ACTP. Accordingly, the counter 141 becomes in a state of being able to update the pull-up impedance adjusting signal DRZQP as a count value of the counter 141. FIG. 9 shows an example that an impedance of the replica buffer 110 is lower than a desired value (240Ω) at the time of activating the impedance adjusting command ZQCOM. In this case, an impedance of the replica buffer 110 increases by each one pitch when a count value is updated in response to the sampling clock ACTP. In the example shown in FIG. 9, when the value of the pull-up impedance adjusting signal DRZQP reaches a-4, the impedance of the replica buffer 110 exceeds the desired value (240Ω), and a logic level of the determination signal COMPP0 is inverted in response to this.

With this configuration, the impedance of the replica buffer 110 is controlled to be reduced at the next time. When this operation is repeated, a logic level of the determination signal COMPP0 changes as high level→low level→high level. This means that the impedance of the replica buffer 110 has become nearest to 240Ω as the resistance value of the external resistor R. Upon detecting this, the determining circuit 181 inactivates the determination signal hitP at a low level.

When the determination signal hitP is inactivated, the control-signal generation circuit 160 finishes an adjustment operation to the pull-up impedance adjusting circuit 180, and shifts to an adjustment operation to the pull-down impedance adjusting circuit 190.

When the adjustment operation is shifted to that to the pull-down impedance adjusting circuit 190, the control-signal generation circuit 160 activates the adjustment enable signal EnableN at a high level, and generates the sampling clock ACTN. Accordingly, the counter 142 becomes in a state of being able to update the pull-down impedance adjusting signal DRZQN as a count value of the counter 142. FIG. 9 shows an example that an impedance of the replica buffer 130 is lower than the desired value (240Ω) at the time of activating the adjustment enable signal EnableN. In this case, an impedance of the replica buffer 130 increases by each one pitch when a count value is updated in response to the sampling clock ACTN. In the example shown in FIG. 9, when the value of the pull-down impedance adjusting signal DRZQN reaches b-3, the impedance of the replica buffer 130 exceeds the desired value (240Ω), and a logic level of the determination signal COMPN0 is inverted in response to this.

With these operations, the impedance of the replica buffer 130 is controlled to be reduced at the next time. When this operation is repeated, a logic level of the determination signal COMPN0 changes as low level→high level→low level.

This means that the impedance of the replica buffer 130 has become nearest to 240Ω as the resistance value of the external resistor R. Upon detecting this, the determining circuit 182 inactivates the determination signal hitN at a low level.

With the above processes, a series of impedance adjustment operations (calibration) is completed. The pull-up impedance adjusting signal DRZQP and the pull-down impedance adjusting signal DRZQN updated by the above impedance adjustment operations are supplied to the output-impedance control circuit 230 shown in FIG. 5, thereby reflecting adjusted impedances to the output buffer 210.

As explained above, according to the present embodiment, in the impedance adjustment of the replica buffer 130 at a pull-down side, an impedance target value does not become an impedance of the replica buffer 120 but becomes an impedance of the calibration terminal ZQ. Therefore, an impedance adjustment error at a pull-up side is not superimposed with an impedance adjustment error at the pull-down side, unlike a superimposition generated by a conventional calibration circuit. As a result, the impedance at the pull-down side can be adjusted in a higher precision.

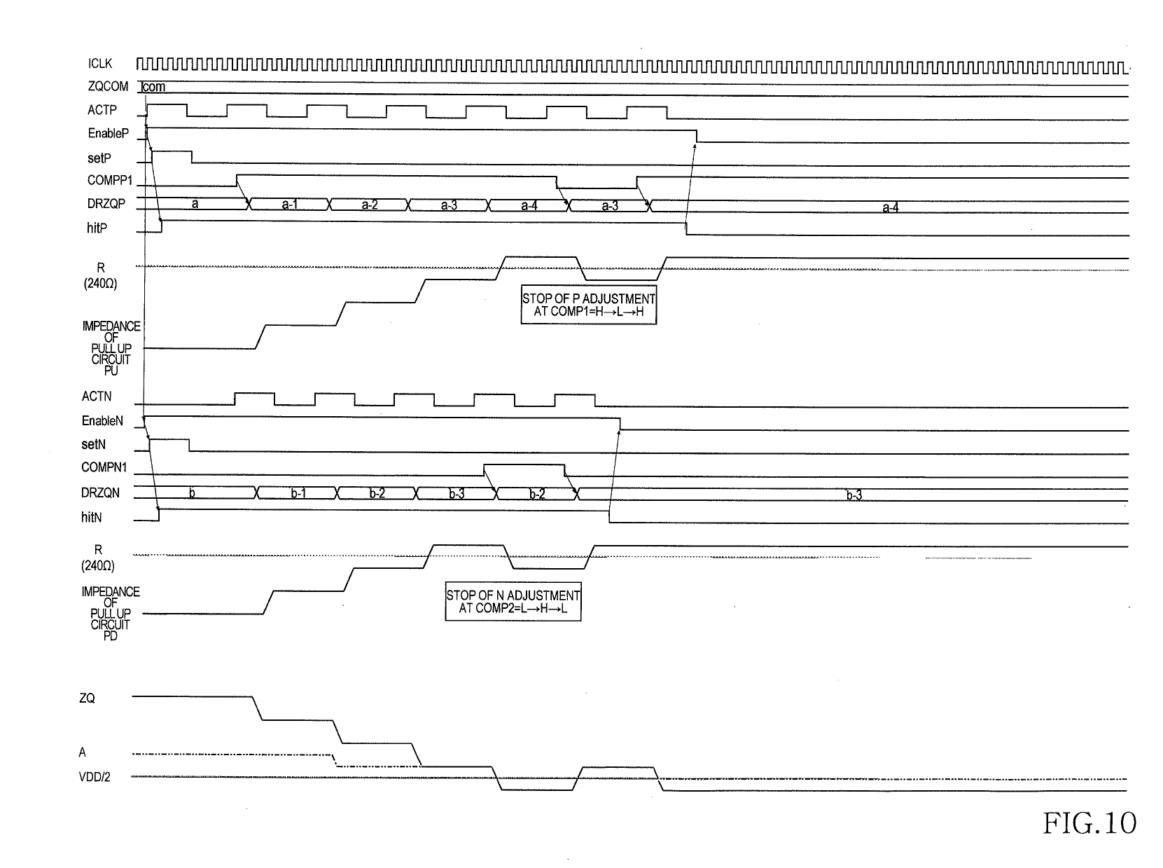

FIG. 10 is a timing diagram for explaining another example of an operation the semiconductor device 10 according to the present embodiment.

In the example shown in FIG. 10, when the impedance adjusting command ZQCOM is activated, the control-signal generation circuit 160 activates both the adjustment enable signals EnableP and EnableN, and generates the sampling clocks ACTP and ACTN. As a result, the adjustment operation to the pull-up impedance adjusting circuit 180 and the adjustment operation to the pull-down impedance adjusting circuit 190 are performed in parallel. Respective operations are identical to those explained with reference to FIG. 9.

According to the example shown in FIG. 10, because the impedance at the pull-up side and the impedance at the pull-down side are adjusted simultaneously, a time required for a series of impedance adjustment operations is shortened. In the present example, during the impedance adjustment of the replica buffer 130 at the pull-down side, the impedance of the replica buffer 120 at the pull-up side changes, but the replica buffer 120 is merely a current source to the replica buffer 130. Even when a current value of the replica buffer 120 changes based on an impedance adjustment, there is no difference in that an impedance target value of the replica buffer 130 becomes a resistance value of the external resistor connected to the calibration terminal ZQ. Therefore, as shown in the example in FIG. 10, even when the impedance at the pull-up side and the impedance at the pull-down side are simultaneously adjusted, both impedances can be correctly adjusted.

It is apparent that the present invention is not limited to the above embodiments, but may be modified and changed without departing from the scope and spirit of the invention.

What is claimed is:

1. A semiconductor device comprising:
a first replica buffer connected to a first terminal;
a first impedance-adjusting circuit that changes an impedance of the first replica buffer based on a difference between a potential of the first terminal and a predetermined potential;
a second replica buffer having a substantially same impedance as that of the first replica buffer;
a third replica buffer connected in series to the second replica buffer;
a second impedance-adjusting circuit that changes an impedance of the third replica buffer based on a difference between a potential of a connection node of the second and third replica buffers and the potential of the first terminal; and
a control-signal generation circuit that controls the first and second impedance-adjusting circuits, so that the first impedance-adjusting circuit changes impedance of the first replica buffer during at least a part of period of time when the second impedance-adjusting circuits changes impedance of the third replica buffer.

2. The semiconductor device as claimed in claim 1, wherein
the first replica buffer is connected between a first power-source wiring supplied with a first power-source potential and the first terminal,
the second replica buffer is connected between the first power-source wiring and the connection node, and
the third replica buffer is connected between the connection node and a second power-source wiring supplied with a second power-source potential.

3. The semiconductor device as claimed in claim 2, further comprising:
an output buffer connected to a second terminal; and
an output-impedance control circuit that adjusts an impedance of the output buffer, wherein
the output buffer includes a first buffer circuit connected between the first power-source wiring and the second terminal, and a second buffer circuit connected between the second terminal and the second power-source wiring, and
the output-impedance control circuit sets an impedance of the first buffer circuit at an impedance which is same as an impedance of the first replica buffer, and sets an impedance of the second buffer circuit at an impedance which is same as an impedance of the third replica buffer.

4. The semiconductor device as claimed in claim 3, wherein a plurality of the output buffers are connected in parallel to the second terminal.

5. A device comprising:
a first terminal;
a first driving circuit coupled to the first terminal, having a first adjustable impedance and driving, when activated, the first terminal to a first logic level with a first adjusted impedance;
a second driving circuit coupled to the first terminal, having a second adjustable impedance and driving, when activated, the first terminal to a second logic level with a second adjusted impedance;
a first control circuit coupled to the first and second driving circuit and changing each of the first and the second adjustable impedance to approach to a reference impedance, the first control circuit terminating changing the each of the first and the second adjustable impedance when the each of the first and the second adjustable impedance has reached or crossed the reference impedance from a first adjusting impedance higher than the reference impedance in response to a third logic level of a selection signal and terminating changing the each of the first and second adjustable impedance when the each of the first and the second adjustable impedance has reached or crossed from a second adjusting impedance lower than the reference impedance in response to a fourth logic level of the selection signal; and
a second control circuit generating the selection signal.

6. The device as claimed in claim 5, further comprising a second terminal configured to be coupled to a reference element that has the reference impedance.

7. The device as claimed in claim 6, wherein the reference element is a reference resistor.

8. The device as claimed in claim 6, wherein the first control circuit includes first and second replica circuits that have respectively first and second replica impedance being substantially equal to the first adjustable impedance and a third replica circuit that has third replica impedance being substantially equal to the second adjustable impedance.

9. The device as claimed in claim 8, wherein the first replica circuit is coupled to the second terminal, the second and the third replica circuit are coupled in series to each other at a first node, the first control circuit further includes first and second comparison circuits, the first comparison circuit compares a voltage level of the second terminal with a predetermined voltage level so as to adjust the first adjustable impedance, and the second comparison circuit compares a voltage level of the first node with the voltage level of the second terminal so as to adjust the second adjustable impedance.

10. The device as claimed in claim 8, wherein the first replica circuit is coupled to the second terminal, the second and the third replica circuit are coupled in series to each other at a first node, the first control circuit further includes first and second comparison circuits and a selection circuit, the selection circuit receiving a first signal indicative of a voltage level of the second terminal and a second signal having a predetermined voltage level, the selection circuit selects and outputs one of the first and second signals, the first comparison circuit compares the voltage level of the second terminal with the predetermined voltage level so as to adjust the first adjustable impedance, and the second comparison circuit receiving the one of the first and second signals so as to compare a voltage level of the first node with one of the voltage level of the second terminal and the reference voltage level so as to adjust the second adjustable impedance.
